(19) United States
(12) Patent Application Publication
(10) Pub. No.: US 2013/0106429 A1
(43) Pub. Date: May 2, 2013

(54) METHOD AND CELL MONITORING UNIT FOR MONITORING AN ACCUMULATOR; CENTRAL MONITORING UNIT AND ACCUMULATOR

(71) Applicant: Axel Krause, Nesslau (CH)

(72) Inventor: Axel Krause, Nesslau (CH)

(73) Assignee: BRUSA ELEKTRONIK AG, Sennwald (CH)

(21) Appl. No.: 13/641,782

(22) PCT Filed: May 2, 2011
(86) PCT No.: PCT/IB2011/051929

§ 371 Date: Nov. 7, 2012

Related U.S. Application Data
(60) Provisional application No. 61/332,725, filed on May 7, 2010.

(30) Foreign Application Priority Data
May 7, 2010 (EP) 10162353

(51) Int. Cl. G01R 31/36

(52) U.S. Cl. CPC G01R 31/36
USPC 324/434

(57) ABSTRACT

A method for monitoring a charge accumulator (1) with several cells (2, 2a . . . 2n), wherein a parameter of a cell (2, 2a . . . 2n) is measured and transmitted to a central monitoring unit (4) by means of a pulse-width modulated signal. The pulse-width modulated signals emanating from the individual cells (2, 2a . . . 2n) are synchronously transmitted and summed. Furthermore, a cell monitoring unit (3, 3a . . . 3n) according to the invention, a central monitoring unit (4) according to the invention and an accumulator (1) according to the invention are set forth for implementing the method.

This application is a 35 U.S.C. 371 national-phase entry of PCT International application no. PCT/IB2011/051929 filed on May 2, 2011 and also claims benefit of priority to prior European application no. EP10162353 filed on May 7, 2010, and also claims priority as a non-provisional of U.S. provisional application Ser. No. 61/332,725 filed on May 7, 2010; both European application no. EP10162353 and U.S. provisional application Ser. No. 61/332,725 are incorporated herein by reference in their entireties for all intents and purposes, as if identically set forth in full herein.

The invention relates to a method for monitoring an accumulator with several cells, in which method a parameter of a cell is measured and transmitted to a central monitoring unit by means of a pulse-width modulated signal. Furthermore, the invention relates to a cell monitoring unit for monitoring a cell of an accumulator, which cell monitoring unit comprises a measuring device for measuring a parameter of the cell as well as a transmitting device for transmitting the measured value by means of a pulse-width modulated signal. Furthermore, the invention relates to a central monitoring unit for monitoring an accumulator with several cells, comprising a receiving device for receiving a measured value of a parameter of a cell by means of a pulse-width modulated signal. Lastly, the invention relates to an accumulator with several cells, which accumulator comprises a cell monitoring unit for each cell or is connected to the aforesaid.

Accumulators are the energy supply of the vast majority of electrically operated mobile devices. In order to attain a required nominal voltage, a required current and/or a required capacity, predominantly several galvanic cells are installed to form an accumulator.

In particular in the case of lithium ion accumulators and lithium polymer accumulators it has been shown that the individual cells during discharge reach different voltage positions, or, when several cells connected in series are charged, without further measures reach different charge states. In order to prevent overcharging or deep discharging, which is detrimental to the cell, and also in order to optimally utilise the capacity of the accumulator, the cells are individually monitored during charging. To this effect, in the case of multicellular accumulators, separate connections for each cell are provided, which connections make it possible to individually charge or discharge an individual cell. Equalisation of these different cell voltages or charge states is also referred to as “balancing”.

In principle, balancing can take place by targeted discharging of individual cells that have a higher level of charge, or by targeted charging of cells that have too low a level of charge. The former can take place, for example, by means of a resistor, by way of which the excess energy is converted to heat. During targeted charging, individual cells are charged with a higher current, or energy of cells with a high energy content is transferred to cells with a low energy content.

In particular, in the case of electrical motor vehicles, which after all comprise very-high-capacity accumulators, over time some relatively complex systems have arisen, on the one hand in order to utilise the capacity of the accumulator in the best-possible manner, and on the other hand in order to ensure a long service life. For example, in some systems a cell monitoring unit is associated with each cell of an accumulator, which cell monitoring unit monitors the charge state, charging and discharging of a cell. Said cell usually communicates with a central monitoring unit associated with the entire accumulator, which central monitoring unit collects the data from all the cell monitoring units and correspondingly controls said cell monitoring units. Usually, the central monitoring unit communicates with a central vehicle control system, which, for example, informs the driver of the distance which the accumulator can still travel. In this arrangement it is of course also possible for parameters other than the cell voltage or cell capacity to be determined or regulated, for example the cell temperature. From the state of the art some examples of such monitoring and control systems are known.

For example, EP 0814556A2 discloses a balancing circuit for an accumulator with several cells connected in series. In this arrangement a monitoring circuit is associated with each cell, which monitoring circuit is connected to a central control device by way of a bus. The monitoring circuits comprise an A-D converter for acquiring the cell voltage and the cell temperature, a microprocessor connected therewith, a data interface connected therewith, and an optocoupler for connection to the bus. Furthermore, the monitoring circuit comprises a reference voltage source. The microprocessor can further emit a pulse-width modulated signal (PWM signal) in order to discharge a cell in a defined manner by way of a resistor.

DE 69828169T2 discloses a further balancing circuit for an accumulator with several cells connected in series. Again, each cell is associated with a monitoring circuit that comprises a driver circuit for the defined discharging of a cell, as well as an A-D converter for determining the cell voltage. By way of an optocoupler each, these units are connected to a central control unit which receives the measured values of the individual monitoring circuits, and specifies voltage values relating to the individual cells. In this arrangement the target voltage value relating to a cell is transmitted to the individual monitoring circuits by the central control device by means of a PWM signal.

WO 2008/055505A1 discloses a further battery management system, in which discharging of a specific cell takes place by way of a resistor, i.e. a shunt that is controlled by means of a PWM signal. In this arrangement the discharge circuit associated with the cell receives a target voltage from a central control unit, which target voltage in the discharge circuit is then converted to a corresponding PWM signal.

WO 2006/108081A2 discloses a balancing circuit in which the voltage signals of several cells of an accumulator are conveyed to a central measuring unit by way of a multiplexer. Furthermore, the cells can be discharged in a targeted manner by way of a shunt that is controlled by means of a PWM signal.

U.S. Pat. No. 6,873,134B2 further discloses a battery management system in which local monitoring circuits, which are associated with a cell of an accumulator, can communicate with a central control unit by way of a bus, and from there they can obtain a target voltage relating to the respective cell concerned.

EP 2085784A2 shows a battery management system for an accumulator with several cells connected in series, in which battery management system data can be transmitted in time division multiplex.

U.S. Pat. No. 6,621,247B1 discloses an electronic monitoring unit for an electrical energy storage system. The measurement devices may be connected in parallel to a joint signal connection and transfer their measurement values in parallel through the joint signal connection, in a form suitable for the determination of minimum and maximum values. The joint signal is transmitted by means of a pulse-width modulated signal.

Finally, EP 1122854B1 shows another electronic monitoring unit for a battery, wherein the measured signals are transmitted by means of a pulse-width modulated signal. In addition, the arrangement comprises potential level changing circuits.

The known systems are associated with a disadvantage in that some of them involve elaborate communication between the cell monitoring units, which are associated with the cells, and the central monitoring unit that is associated with the accumulator.

It is thus the object of the invention to state an improved method and an improved cell monitoring unit for monitoring an accumulator, as well as an improved central monitoring unit and an improved accumulator. In particular, communication between the units involved is to be improved.

According to the invention, this object is met by a method of the type mentioned in the introduction, in which the pulse-width modulated signals emanating from the individual cells are synchronously transmitted and summed.

The object of the invention is further met by a cell monitoring unit of the type mentioned in the introduction, in which the transmitting device is equipped for transmitting the measured value as a summand of a sum signal synchronously with other cell monitoring units.

Moreover, the object of the invention is met by a central monitoring unit of the type mentioned in the introduction, in which the receiving device is equipped to receive a sum signal whose summands represent the measured values of the individual cells.

Finally, the object of the invention is met by an accumulator with several cells, which accumulator for each cell comprises a cell monitoring unit according to the invention, or is connected with said cell monitoring unit.

According to the invention, the measured values of all cell monitoring units can be transmitted at one time to the central monitoring unit, in other words during a single measured-value transmission. In other words, transmitting the measured values takes place particularly quickly without this requiring relatively high clock frequencies for data transmission, as is the case during sequential transmission of measured values. Although the transmission of the measured values takes place quickly, there is no loss of information because the single measured values can be extracted out of the sum signal if desired.

Moreover, by means of a pulse-width modulated signal (PWM signal) measured values can be transmitted reliably, in other words largely unaltered, even over extended distances or in an environment that is problematic in terms of the electromagnetic fields. In this arrangement a measured value is converted to a pulse duty factor with constant frequency. In particular when compared to systems that transmit measured values in an analogue manner, for example by way of a current loop, this provides a significant advance because measured values that are transmitted in an analogue manner can easily be altered as a result of the electromagnetic fields prevalent in an electric motor vehicle, which fields are, for example, caused by the drive motor or by an inverter. When compared to known systems, too, in which systems measured values are already transmitted digitally, the invention also represents an advance because a voltage PWM converter, which in a cell monitoring unit is frequently used anyway for controlling a shunt for balancing, can now have a dual use. According to the invention, said voltage PWM converter not only receives voltage signals from a central monitoring unit, which signals are used for generating a PWM signal for the shunt, but the voltage PWM converter can now also convert the cell voltage to a PWM signal and can transmit it in such a manner to the central monitoring unit. Of course, it is also possible to use two separate PWM converters for this task.

Advantageous embodiments and improvements of the invention are presented or disclosed in the present disclosure including the description in conjunction with the figures of the drawings.

It is advantageous if a step in the stepped signal resulting from summing is interpreted in the central monitoring unit as a measured value of a cell, and if the measured value is isolated from the sum signal. If the height of a step, caused by a measured value, in the stepped sum signal is known, the arrangement and height of the step can allow conclusions relating to its distribution. It is also possible to isolate a single measured value from the sum signal.

It is particularly advantageous if the first and/or last step in the stepped signal resulting from summation are/is interpreted in the central monitoring unit as an extreme value of the measured parameter within the accumulator, and if the measured value is isolated from the sum signal. The first and the last steps in the sum signal correspond to the extreme values occurring in the accumulator. For example, if the cell voltage is provided as the measuring parameter, then the first and the last steps correspond to the lowest and the highest cell voltages within the accumulator. With this variant of the invention it is thus possible to very quickly determine extreme values occurring within an accumulator.

It is advantageous if in the central monitoring unit for isolation of a measured value it is detected whether the stepped signal passes an intensity level specified between two steps. If the height of the step caused by a measured value is known, an intensity level between two horizontal sections of the steps (if the time is projected onto the horizontal axis) or vertical sections of the steps (if the time is projected onto the vertical axis) can be set, and waiting for the sum signal to pass this intensity level can take place. The point in time of passing indicates the duty factor of the PWM signal associated with this measured value, and thus indicates the measured value itself.

A variant of the method according to the invention, in which method sequentially in each case a measured value is transmitted individually to the central monitoring unit is also particularly advantageous. If the steps caused by the individual measured values all have the same height, then simultaneous transmission of all the measured values is possible, but it is not possible to associate a particular measured value with a particular cell. However, in this variant of the invention a measured value is individually transmitted sequentially so that in the central monitoring unit it is known which measured value is specifically associated with which cell.

In this context it is advantageous if the measured value transmitted individually to the central monitoring unit is transmitted in parallel to the sum signal. In this variant of the invention, parallel to the individually transmitted measured value all the remaining measured values are transmitted in the form of a sum signal so that during each measured value transmission in addition to an individual measured value the extreme values occurring in an accumulator can be determined.

In this context it is furthermore advantageous if the measured value that is individually transferred to the central monitoring unit is excluded from summation. In this variant of the invention the individually transmitted measured value is excluded from summation in order to avoid redundant transmission of measured values.

It is favourable if the deviation of the cell parameter from a reference value provided for each cell is used as a measured value. In order to be able to determine the measured value at the best possible resolution, in this variant of the invention a deviation of the cell parameter from a reference value is transmitted. In this manner it is possible, for example, to deduct an “offset” which anyway is always present or at least is frequently present. For example, if the cell temperature is used as a cell parameter, then for example the deviation of the temperature from 20° C. can be transmitted as the measured value, because 20° represents the norm, and values below −20° and +80° are likely to occur rather rarely. The range which in this manner has been limited to ΔT=100° C. can thus be transmitted with good measured value resolution. Measured values outside the range are transmitted as a measured value overflow.

It is also advantageous if

reference values of adjacent cells, which reference values are used for acquiring measured values and are provided for each cell, are compared to each other in a periodically recurring manner, and

an error message is issued if the deviation exceeds a specifiable limiting value.

Frequently, reference values are required for determining measured values. For example, in a cell monitoring unit a reference voltage source can be provided when the cell voltage is used as a measuring parameter. In order to allow detection of (undesired) change of this voltage standard, the reference value of a cell monitoring unit is compared to a reference value of another cell monitoring unit. If the difference is unexpectedly high, then one of the two reference standards is probably defective. In this context the term “adjacent” does not necessarily mean locally adjacent but rather “electrically” adjacent. For example, two cells that are electrically interconnected are “electrically” adjacent, but they need not be arranged in direct local proximity to each other.

It should be noted that the above-mentioned variant of the invention can be advantageous even without the characteristics mentioned with the remaining variants, and can thus provide the basis of an independent invention.

It is favourable if the voltage and/or the temperature of the cell are/is provided as parameters. These two parameters are particularly meaningful in relation to a cell. For example, by monitoring the cell voltage, overcharging or deep discharging of said cell can be avoided. Likewise by monitoring the temperature of the cell, operation outside a permissible or optimal operating range can be prevented.

It is particularly advantageous if the measured voltage and the measured temperature are used to activate a heater which is connected to the terminals of a cell and is thermally coupled to the cell when a limiting value relating to the cell voltage is exceeded, or when a limiting value relating to the cell temperature is not reached. In this variant, a shunt arranged parallel to the cell is not only used to discharge a cell in a targeted manner in the case of overvoltage, in other words to undertake balancing, but also to heat the cell in the case of too low a temperature. As a rule, at too low a temperature a cell can produce only a reduced output, and for this reason it may in some circumstances be sensible to heat the cell to operating temperature prior to its use. In this variant of the invention for this purpose the shunt that is present anyway for balancing is used, which shunt in this manner provides a dual benefit. In order to achieve an optimum heating effect, thermal coupling between the cell and the shunt should be designed in a corresponding manner, for example with the use of heat transfer compounds, air circulation and the like.

It should be noted that the above-mentioned variant of the invention can be advantageous even without the characteristics mentioned with the remaining variants, and can thus provide the basis of an independent invention.

In the above variant it is advantageous if the heater is regulated in such a manner that the cell voltage and/or the cell temperature maintain/maintains a specified setpoint value or a setpoint range. Thus, in this variant of the invention not only are limiting values in the sense of a maximum cell voltage and/or a minimal cell temperature specified, but a setpoint value or a setpoint range relating to a cell parameter is specified. This means, for example, a setpoint cell voltage or a minimum and a maximum cell voltage and/or a setpoint cell temperature or a minimum and a maximum cell temperature are specified.

When regulating a cell parameter it is also advantageous if transmitting a setpoint value takes place by means of a pulse-width modulated signal. In this variant of the invention a setpoint value is transmitted from the central monitoring unit by means of a PWM signal to the cell monitoring unit, analogous to measured-value transmission from a cell monitoring unit to the central monitoring unit. In an advantageous manner in this way the structure (transducer, data lines, etc.), which structure exists anyway for measured-value transmission, can also be used for transmission of a setpoint value. In this arrangement it is also advantageous that a setpoint value can be sent to several cell monitoring units at the same time, and in that location said setpoint value is locally used for determining a setting value; in other words the actual regulation takes place in the cell monitoring unit. This is in contrast to the solutions known from the state of the art, in which solutions the central monitoring unit determines separate setting values in relation to each cell monitoring unit and subsequently transmits them individually; in other words the actual regulation takes place in the central monitoring unit. This arrangement requires comparatively complex communication between the central monitoring unit and the cell monitoring units, whereas in the variant according to the invention, which involves relatively small quantities of data, it is sufficient to do with regulation of a cell parameter, in particular the cell voltage and/or the cell temperature.

Furthermore, it should be mentioned that the variants mentioned in relation to the method according to the invention, and the advantages resulting thereof, equally apply to the cell monitoring unit according to the invention, the central monitoring unit according to the invention, and the accumulator according to the invention, and vice versa.

Finally, it should be noted that the method according to the invention or the cell monitoring unit according to the invention as well as the central monitoring unit according to the invention can be implemented in software and/or in hardware. If the invention is implemented in software, a program that runs on a microprocessor or on a microcontroller carries out the steps according to the invention. Of course, the invention can also be implemented only in hardware, for example by means of an ASIC (Application Specific Integrated Circuit). However, the ASIC can also comprise a processor. Finally, part of the invention can be implemented in software, while another part can be implemented in hardware.

The above embodiments and improvements of the invention can be combined in any desired manner.

Below, the present invention is explained in more detail with reference to the exemplary embodiments shown in the diagrammatic figures in the drawings. The following are shown:

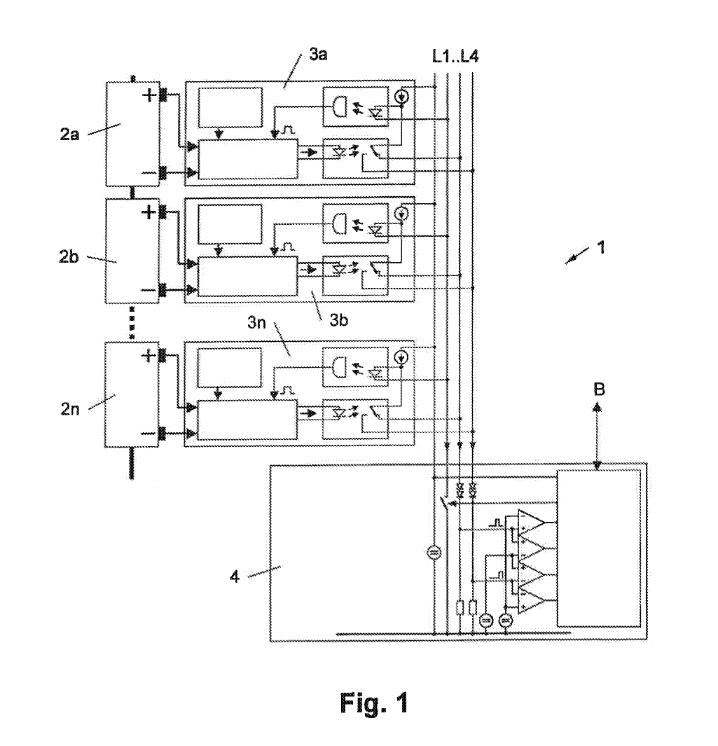

FIG. 1 a diagrammatic overview of a first accumulator according to the invention;

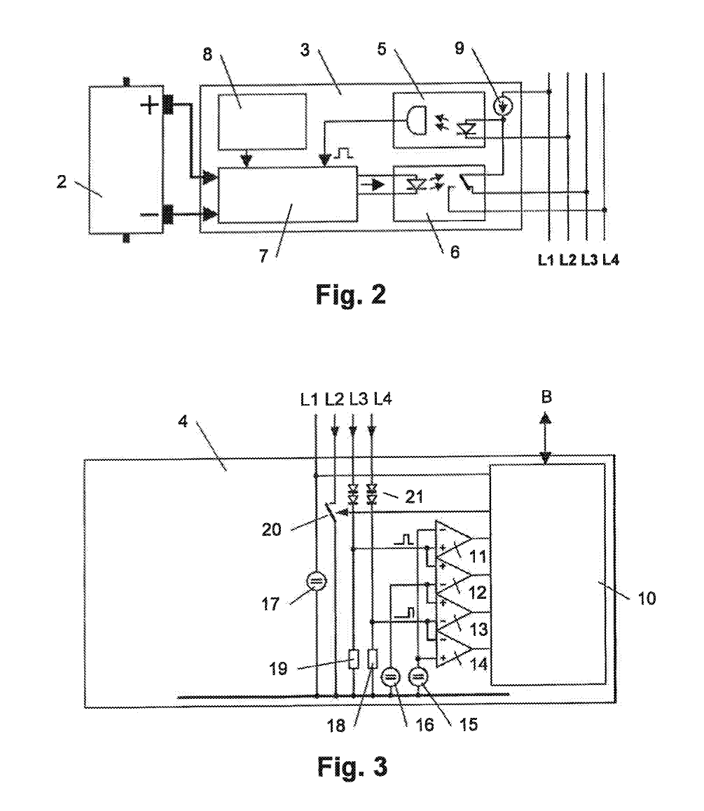

FIG. 2 a detailed view of a first cell monitoring unit according to the invention;

FIG. 3 a detailed view of a first central monitoring unit;

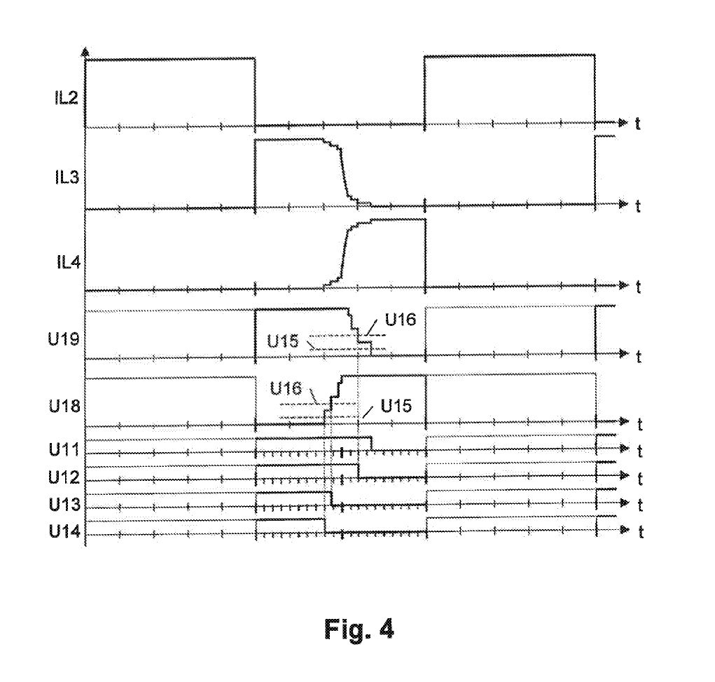

FIG. 4 the chronological sequence of various signals occurring in an accumulator according to the invention, in particular of a sum signal formed from individual measured values;

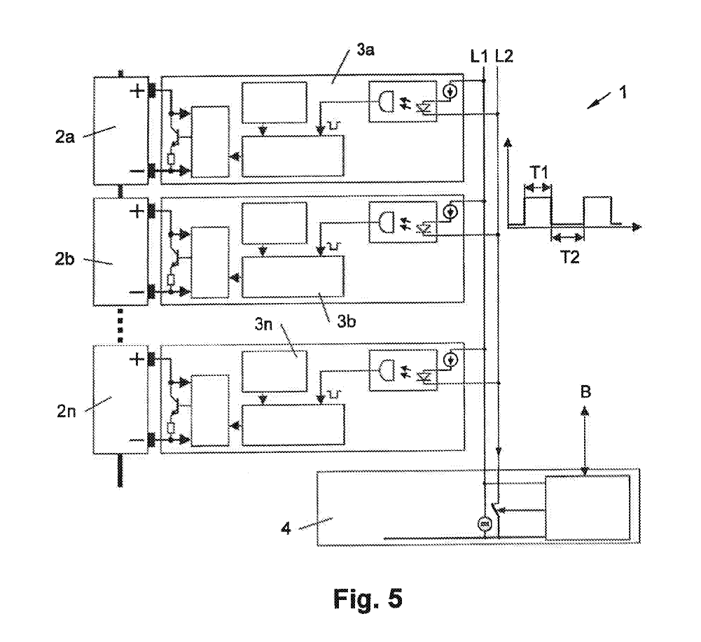

FIG. 5 a diagrammatic overview of a second variant of an accumulator according to the invention;

FIG. 6 a detailed view of a second cell monitoring unit according to the invention;

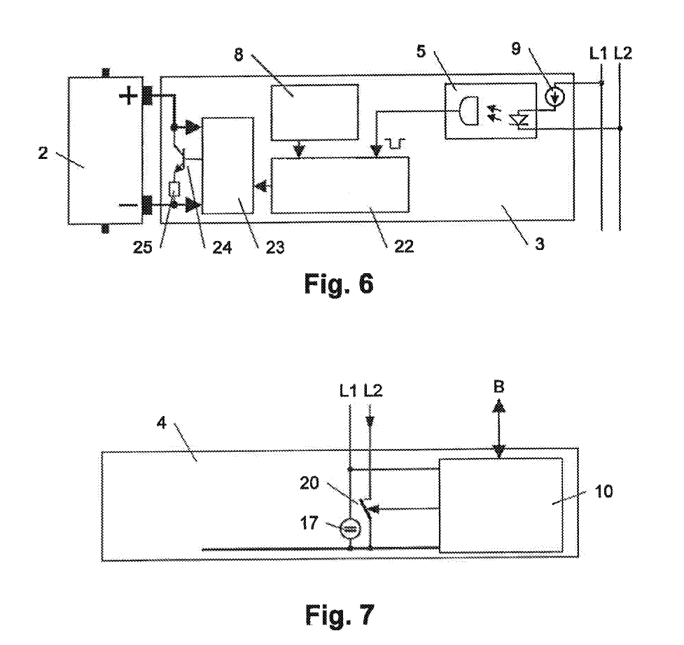

FIG. 7 a detailed view of a second central monitoring unit;

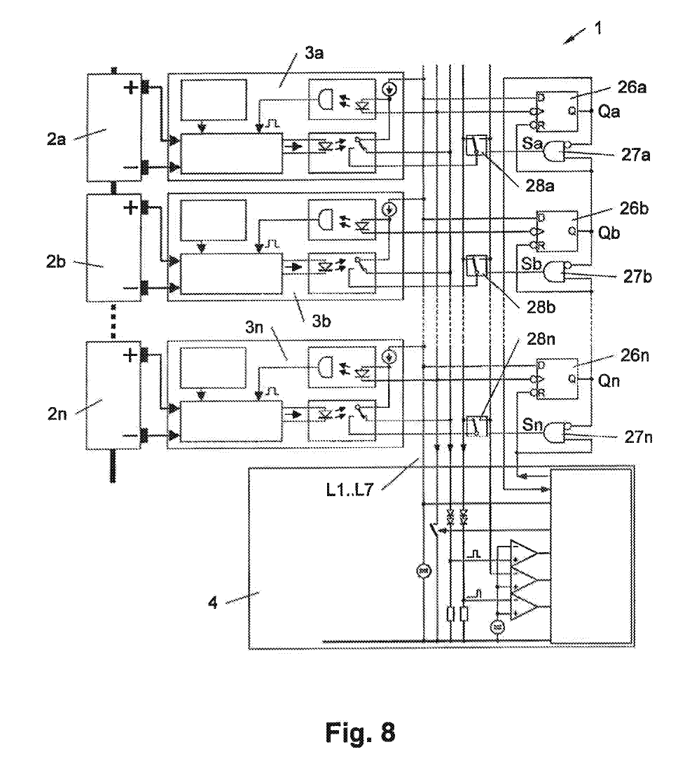

FIG. 8 a diagrammatic overview of a further variant of an accumulator according to the invention;

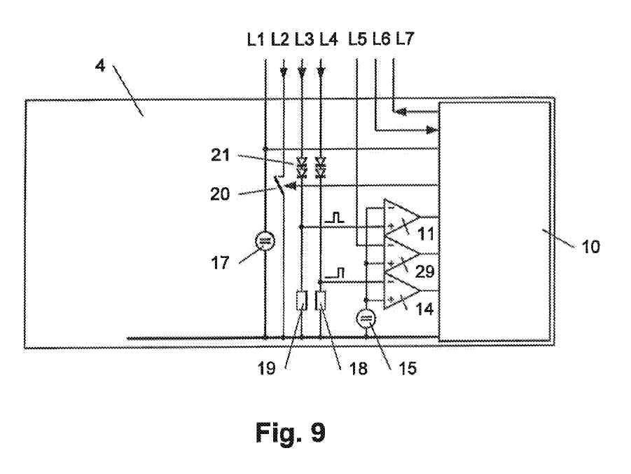

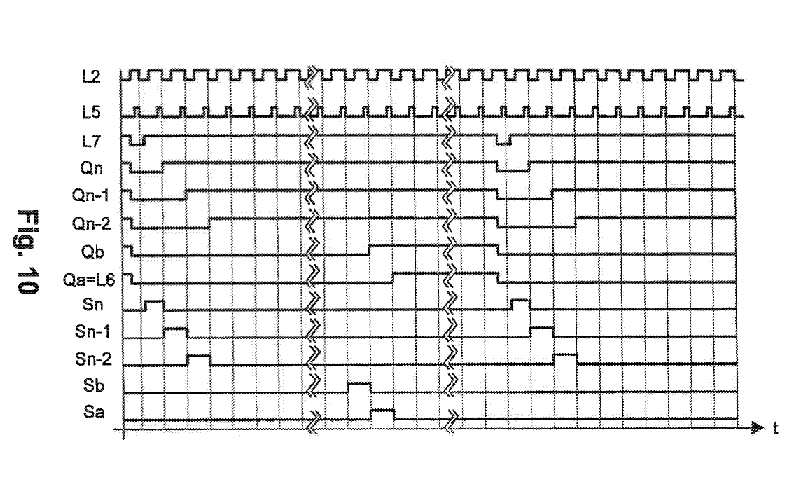

FIG. 9 a detailed view of a further central monitoring unit;

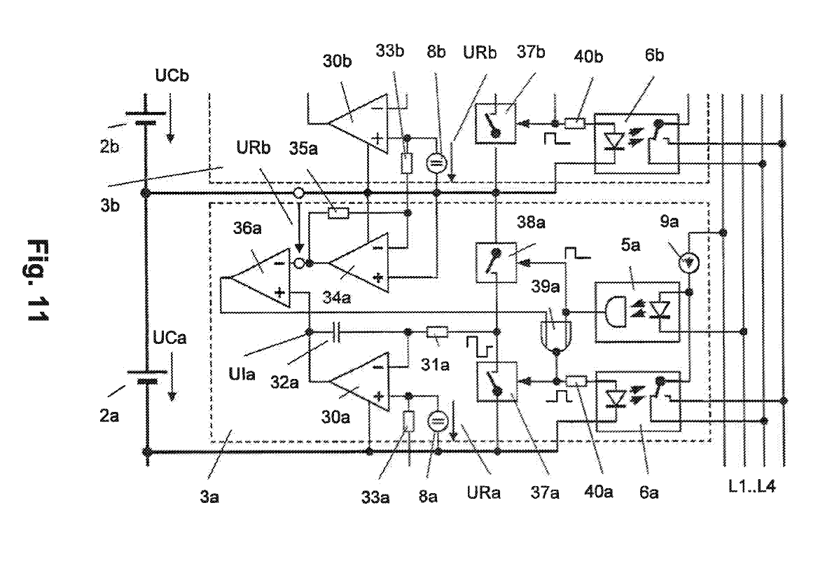

FIG. 10 the chronological sequence of various signals occurring in the accumulator according to the invention according FIG. 8;

FIG. 11 an exemplary circuit for monitoring a reference source of a cell monitoring unit; and

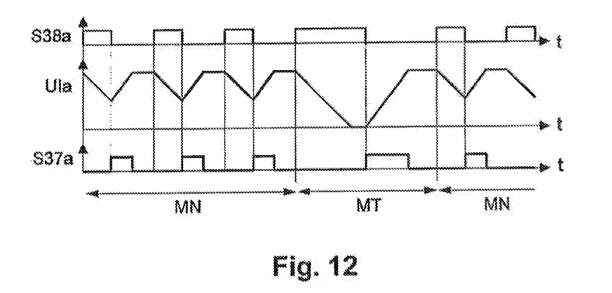

FIG. 12 the chronological sequence of various signals occurring in the circuit according to FIG. 11.

Unless otherwise stated, in the figures of the drawing, identical and similar components with identical reference characters and functionally similar elements and characteristics have the same reference characters but different indices unless otherwise indicated.

FIG. 1 shows a battery 1 comprising several cells 2a . . . 2n with identically constructed cell monitoring units 3a . . . 3n connected to the aforesaid, as well as a central monitoring unit 4. The cell monitoring units 3a . . . 3n are connected to the central monitoring unit 4 by way of signal lines L1 . . . L4. Finally, the central monitoring unit 4 is connected to further control units (not shown) by way of a data bus B.

FIG. 2 shows a detailed view of a cell monitoring unit 3 of FIG. 1, which is connected to a cell 2. The cell monitoring unit 3 comprises an optocoupler 5 on the input side and an optocoupler 6 on the output side. While these are advantageous in the context of the invention, they are, however, not mandatory, because the connection of the cell monitoring unit 3 to the signal lines L1 . . . L4 can also take place in some other manner, for example by way of isolating transformers. The cell monitoring unit 3 further comprises a transducer 7 and a reference source 8. The transducer 7 is connected to the optocoupler 5 on the input side, to the optocoupler 6 on the output side, and to the reference source 8. Finally, on the input side a current source 9 is arranged.

FIG. 3 shows a detailed view of the central monitoring unit 4 of FIG. 1. Said central monitoring unit 4 comprises a microcontroller 10, several comparators 11 . . . 14, three voltage sources 15 . . . 17, two resistors 18, 19, a switch 20 as well as diodes 21.

Below, the function of the accumulator 1 according to the invention is explained in more detail with reference to FIGS. 1 to 4.

By way of the second signal line L2, the central monitoring unit 4 sends a reference pulse sequence of a defined pulse duration (e.g. 0.5 ms) and a defined frequency (e.g. 1 kHz) to all the cell monitoring units 3a . . . 3n. To this effect the switch 20 is in a corresponding manner periodically controlled by the microcontroller 10. During closing of the switch 20 the electric circuit between the voltage source 17, the current sources 9, the optocouplers 5 and the ground connection is closed. In this manner the signal impressed on the switch 20 is sent to the cell monitoring units 3a . . . 3n where it is used as a reference pulse for the transducers 7. In this context FIG. 4 shows the current in the second signal line L2, which current represents a central reference signal or clock signal.

By means of the reference source 8 and the reference pulse, each cell monitoring unit 3a . . . 3n generates a measuring pulse that is synchronous with the reference pulse, with the duration of said measuring pulse depending in a linear manner on the measured value. In the present example the cell voltage is provided as a measuring parameter, and a reference voltage source is correspondingly provided as a reference source 8. Analogously, for example, the cell temperature could be provided as a measured value, and a reference temperature source could be provided as a reference source 8. Frequently a temperature sensor converts a temperature to a resistance value or to a voltage. In such an arrangement, correspondingly, a reference resistance or again a reference voltage source or a reference current source can be used as a reference source 8.

In the present example, by means of the transducer 7 a pulse-width modulated signal (PWM signal) is generated from a voltage signal. For example, a rising/falling flank of a periodic signal of constant frequency is shifted by 0.25 ms per volt of deviation of the measured value from a reference value of 2V. Thus the deviation of a cell parameter from a reference value provided for each cell is used as a measuring value. This measuring pulse predominantly takes place in the pause between two reference pulses.

Thereafter, by way of the optocoupler 6 on the output side, alternately the first line L1 is connected to the third line L3 or the first line L1 is connected to the fourth line L4. Because of the current source 9, by way of the resistors 18 and 19 a voltage signal is generated in the central monitoring unit 4. If several optocouplers 6 are operated at the same time, the current sources 9 are connected in parallel, thus generating a sum current which manifests itself in an increased voltage value at the resistors 18 and 19. As a rule, the voltages of the cells 2a . . . 2n differ, and consequently, due to the respective individual PWM signal, the optocouplers 6 are activated at different points in time. Thus, summing of the PWM signals results in a stepped sum signal.

In this context, FIG. 4 shows the currents IL3, IL4 in the third signal line L3 and in the fourth signal line L4, each showing a sum signal formed from the individual measured values. In this arrangement the sum signal on line L3 is the “quasi-inverse” signal of the signal on line L4.

Thus, transmission of a measured value takes place by means of a pulse-width modulated signal, wherein the pulse-width modulated signals originating from the individual cells 2a . . . 2n are transmitted and summed synchronously.

In the present case it is assumed that all the current sources 9 supply the same current. Therefore the individual steps are identical in height, provided each current source is activated at a different point in time. However, it is also imaginable for each current source 9 to supply a different current so that the actually transmitting cell monitoring unit 3a . . . 3n can be determined by way of the height of the resulting step. In this arrangement it is particularly advantageous if the currents are binary coded currents so that, for example, the current of the cell monitoring unit 3b is twice as high as the current of the cell monitoring unit 3a, and the subsequent current is four times as high etc. However, the actually transmitting cell monitoring unit 3a . . . 3n can also be determined in some other manner, as will be explained further below.

The voltage gradients U19 and U18 in FIG. 4 show the voltage that is dropping at the resistors 19 and 18 due to the impressed current. In this arrangement U18 shows the quasi-increased gradient of IL4 in the case of low current values, U19 shows the quasi-increased gradient of IL3 in the case of low current values. The diagram also shows that the gradients are curtailed. This is caused by the diodes 21 which limit the voltage on the resistors 18 and 19 due to the exponential current-voltage characteristic of the diodes 21.

By means of the voltage source 15 a voltage threshold value or a voltage level U15 is applied to the comparators 11 and 14, which voltage source 15 corresponds to half the voltage of the voltage caused by a current source 8. Analogously, by means of the voltage source 16 a voltage threshold value or a voltage level U16 is applied to the comparators 12 and 13, which voltage source 16 corresponds to one and a half times the voltage of the voltage caused by a current source 9.

If the voltage U18 now exceeds the first voltage level, the comparator 14 generates a falling flank in its output voltage U14. The voltage signal U14 thus corresponds to the PWM signal of that cell monitoring unit 3a . . . 3n which has determined the lowest measured value within the accumulator 1. If the voltage U18 now exceeds the second voltage level, the comparator 13 generates a falling flank in its output voltage U13. The voltage signal U13 thus corresponds to the PWM signal of that cell monitoring unit 3a . . . 3n which has determined the second-lowest measured value within the accumulator 1.

If the voltage U19 falls below the second voltage level U16, the comparator 12 generates a falling flank in its output voltage U12. The voltage signal U12 thus corresponds to the PWM signal of that cell monitoring unit 3a . . . 3n which has determined the second-highest measured value within the accumulator 1. If the voltage U19 now falls below the first voltage level U15, the comparator 11 generates a falling flank in its output voltage U11. The voltage signal U11 thus corresponds to the PWM signal of that cell monitoring unit 3a . . . 3n which has determined the highest measured value within the accumulator 1.

Advantageously, in this manner within a measuring cycle simultaneously the highest, the second-highest, the lowest and the second-lowest measured values can be acquired by the central monitoring unit 4.

A step in the stepped signal IL3, IL4, U18, U19, which signal results from summing, is thus interpreted in the central monitoring unit as a measured value of a cell 2a . . . 2n, and at least one measured value is isolated from the sum signal IL3, IL4, U18, U19. The first and/or the last step in the stepped signal IL3, IL4, U18, U19 which results from summing is furthermore interpreted in the central monitoring unit 4 as an extreme value of the measured parameter within the accumulator 1, and the respective measured value is isolated from the sum signal IL3, IL4, U18, U19. To this effect the central monitoring unit 4 detects whether the stepped signal U18, U19 passes an intensity level U15, U16 specified between two steps.

FIG. 5 shows a further variant of the accumulator 1 according to the invention. Said accumulator 1 is very similar to the accumulator 1 shown in FIG. 1, it comprises several cells 2a . . . 2n with cell monitoring units 3a . . . 3n connected to the aforesaid and constructed in the same manner, as well as a central monitoring unit 4. The cell monitoring units 3a . . . 3n are connected to the central monitoring unit 4 by way of signal lines L1, L2. Finally, the central monitoring unit 4 is connected to further control units (not shown) by way of a data bus B.

FIG. 6 shows a detailed view of a cell monitoring unit 3 of FIG. 5. The cell monitoring unit 3 comprises an optocoupler 5 on the input side, a setting-value converter 22, a reference source 8, a cell regulator 23, a transistor 24 and a resistor 25. Finally, on the input side a current source 9 is arranged. The setting-value converter 22 is connected to the optocoupler 5 on the input side, to the reference source 8 and to the cell regulator 23. The setting-value converter 22 is connected to the cell regulator 23. The latter is finally connected to the cell 2 and controls a series connection which is arranged between the connections of the cell 2 and which comprises the transistor 24 and the resistor 25.

As is the case with the accumulator 1 shown in FIG. 1, while the optocoupler 5 on the input side is advantageous in the context of the invention, it is not at all mandatory, because the connection of the cell monitoring unit 3 to the signal lines L1 . . . L2 can also take place in some other manner, for example by way of isolating transformers, input amplifiers and the like.

FIG. 7 shows a detailed view of the central monitoring unit 4 of FIG. 5. Said central monitoring unit 4 comprises a microcontroller 10, a voltage source 17 and a switch 20.

The function of this variant of the invention is now explained in more detail with reference to the accumulator 1 shown in FIGS. 5 to 7.

It is the object of this circuit variant to equalise differences between the individual cells 2a . . . 2n in relation to a particular parameter. In the present case the individual cell voltages are to be balanced. Of course, other cell parameters, for example the cell temperature, could be balanced by means of the present variant of the invention.

To this effect the microcontroller 10 specifies a setpoint value, namely in the form of a PWM signal, by variation of the times T1 and T2. To this effect the switch 20 is pulsed accordingly, and the signal is forwarded in this manner, by way of the lines L1 and L2, to all cell monitoring units 3a . . . 3n. By way of the optocoupler 5 on the input side, the actuating signal is forwarded to the setting-value converter 22 which by means of the reference source 8 (in the present example a reference voltage source) from the PWM signal generates an actuating signal in the form of a level (in the present example a voltage level). This voltage level is entered as a setpoint value in the cell regulator 23, which compares said setpoint value with the voltage measured at the terminals of the cell 2, and which cell regulator 23 activates the transistor 24 when the cell voltage is too high. By way of the resistor 25 the excessive cell voltage is reduced and converted to heat.

In a particularly advantageous variant of the invention, furthermore a setpoint value relating to a cell temperature can be specified, which setpoint value is transmitted analogously to the setpoint value relating to the cell voltage by means of a PWM signal. If the cell temperature is too low, the transistor 24 is also activated, in this case to heat the cell 2. In this arrangement good heat transfer between the cell 2 and the resistor 25 should be ensured.

Thus the measured voltage and the measured temperature are used to activate a heater (in the present example in the form of the resistor 25), which is connected to the terminals of a cell 2 and which is thermally coupled to the cell 2 when a limiting value relating to the cell voltage is exceeded, or when a limiting value relating to the cell temperature has not been reached.

It should be noted that the variant of the invention shown in FIG. 1 could also be combined with the variant shown in FIG. 5 so that a system is obtained that combines the functionality of the circuit shown in FIG. 1 with the functionality of the circuit shown in FIG. 5. Of course, certain functions can also be shared. This is directly obvious, for example, in the case of the optocoupler 5 on the input side, the reference source 8, the microcontroller 10 etc. Likewise, the function of the transducer 7 and of the setting-value converter 22 can be carried out by one and the same component, for example by a voltage-PWM converter, which is repeatedly supplied alternately with a measured value and a setting value.

It should further be noted that the division into separate units, as shown in FIGS. 1 to 11, need not necessarily be physically implemented in the form shown. Of course, several functional blocks can be taken together in one component. For example, the cell monitoring unit 3 can essentially comprise a single module, for example comprising a microcontroller, in which the individual functional blocks are formed by circuit components of the microcontroller and/or corresponding software routines. Implementation in the form of an ASIC (Application Specific Integrated Circuit) is also possible.

FIG. 8 shows a further variant of the accumulator 1 according to the invention, which is very similar to the accumulator shown in FIG. 1. However, instead of four lines L1 . . . L4, the present arrangement comprises seven lines L1 . . . L7, additional D-flip-flops 26a . . . 26n, additional AND gates 27a . . . 27n, additional changeover switches 28a . . . 28n and a modified central monitoring unit 4 which is explained in more detail below with reference to FIG. 9.

FIG. 9 shows the central monitoring unit 4 of FIG. 8 which comprises a microcontroller 10, three comparators 11, 14 and 29, two voltage sources 15 and 17, two resistors 18, 19, a switch 20 as well as diodes 21.

The function of the accumulator 1 according to the invention is explained in more detail with reference to FIGS. 8 to 10. For the sake of simplicity the explanations are limited to the differences compared to the function of the accumulator 1 shown in FIG. 1.

At the output of each cell monitoring unit 3a . . . 3n there is a changeover switch 28a . . . 28n, by means of which the output of an optocoupler 6 on the output side can be switched as desired between the fourth signal line L4 and the fifth signal line L5. In this arrangement the changeover switches are controlled by the D-flip-flops 26a . . . 26n.

By means of a pulse-shaped reset signal on the line L7, all the D-flip-flops 26a . . . 26n are reset so that their output Qa . . . Qn assumes the value zero. Shortly after commencement of the reference pulse on the line L2 (low active) the reset signal is set to high (inactive). As a result of this the output of the cell monitoring unit 3n is switched to the fifth line L5.

Then follows the measured-value transmission, which has already been explained in the context of FIG. 4. In contrast to the sequence explained in the context of FIG. 4, in the present embodiment the measured value of the cell monitoring unit 3n is excluded from the sum signal and instead is transmitted individually by way of the line L5.

At the start of the next reference pulse on the second line (negative flank) the D-flip-flop 26n is set to Qn=high. Thereby the output of the cell monitoring unit 3n is separated from the line L5 and is connected to the sum signal L4; however, the output of the cell monitoring unit 3n−1 is switched to the line L5 so that its measured value can be transmitted individually. In this manner successively all the cell monitoring units 3a . . . 3n are individually switched to the line L5, and the measured values are transmitted individually. When the D-flip-flop 26a is set (Qa=high), the entire strand comprising the cell monitoring unit 3a . . . 3n is run through. In order to ensure synchronisation, the output of the D-flip-flop 26a is fed back to the microcontroller 10 by way of the line L6 so that the end of a measuring cycle is displayed. A new measuring sequence can then be started on the line L7 by means of a new reset pulse.

The changeover switches 28a . . . 28n are thus successively controlled individually by means of a type of shift register that is formed by the interlinked D-flip-flops 28a . . . 28n so that all the PWM signals of the individual cells 2a . . . 2n can successively be individually transmitted by way of the signal line L5 and can be evaluated. In this arrangement the AND gates 27a . . . 27n are used for correctly controlling the changeover switches 28a . . . 28n.

The measured value in each case transmitted by way of the line L5 is individually evaluated by way of the comparator 28. As a result of the time division multiplex, no special addressing of the cell monitoring units 3a . . . 3n is necessary, in other words it is handled by said time division multiplex. However, since the remaining measured values continue to be transmitted as sum signals, as already mentioned, from the sum signal it is possible to determine the highest measured value within the sum signal by way of the comparator 11, and the lowest measured value within the sum signal by way of the comparator 14. Furthermore, in the microcontroller 10 a comparison can be made as to whether the measured value individually transmitted by way of the line L5 exceeds the highest value from the sum signal or fails to reach the lowest value from the sum signal. In this manner by means of a measured-value transmission (not to be confused with the measuring cycle implemented by means of the D-flip-flops 26a . . . 26n) an individual measured value of a cell 2a . . . 2n, as well as the highest and the lowest measured values within the accumulator 1, can be determined. Of course, this principle of the measured-value transmission is not limited to determining cell voltages, but as an alternative or in addition it is also possible for other cell parameters, for example the cell temperature, to be transmitted in this manner.

Thus in the present variant of the invention successively in each case a measured value is excluded from summation and is individually transmitted to the central monitoring unit 4.

FIG. 11 shows a further variant of the invention. The diagram shows a cell monitoring unit 3a and a section of a cell monitoring unit 3b (in this arrangement shown so as to be above rather than below as is the case in the other figures). Specifically, FIG. 11 shows units that are provided to balance a reference value, in the present case a reference voltage. In an actual embodiment of a cell monitoring unit 3a . . . 3n the units shown in the figures so far can, of course, be provided in addition in a cell monitoring unit 3a . . . 3n. In other words, a cell monitoring unit 3 can contain all the units shown in FIGS. 2, 6 and 8.

The cell monitoring unit 3a comprises an optocoupler 5a on the input side, an optocoupler 6a on the output side, a reference source 8a (in the present case designed as a reference voltage source) and a current source 9a. Furthermore, the cell monitoring unit 3a comprises an operational amplifier 30a on whose positive input the reference voltage source 8a is connected, which operational amplifier 30a together with the resistor 31a and the capacitor 32a forms an integrator. Furthermore, a resistor 33a is connected to the positive input of the operational amplifier 30a, which resistor 33a is provided for connection to a further cell monitoring unit. Furthermore, the cell monitoring unit 3a comprises an operational amplifier 34a whose positive input is connected to the positive terminal of the cell 2a and which together with the resistors 35a and 33b forms a summing amplifier. The outputs of the operational amplifiers 30a and 34a are connected to a comparator 36a. The cell monitoring unit 3a also comprises a switch 37a, by means of which the input of the integrator can be switched to the minus terminal of the cell 2a, and a switch 38a by means of which the input of the integrator can be switched to the plus terminal of the cell 2a. Furthermore, the cell monitoring unit 3a comprises a NOR gate 39a to whose inputs the output of the optocoupler 5a on the input side and the output of the comparator 36a are led. The output of the NOR gate 39a is led to the control input of the switch 37a and, by way of a resistor 40a, to the input of the optocoupler 6a on the output side.

The function of the circuit shown in FIG. 11 is now explained with reference to FIG. 12 which shows the chronological sequences of the input signal S37a of the switch 37a, of the input signal S38a of the switch 38a, as well as the output voltage of the integrator UIa. A distinction is made between a normal mode MN and a test mode MT.

During the normal mode MN the voltage UCa-URa is negatively integrated by means of the integrator (operational amplifier 30a) during the reference period T1 (see also FIG. 5). In this arrangement the switch 38a is closed and the switch 37a is open. After the reference period T1 the optocoupler 6a on the output side is switched over, and the reference voltage URa is positively integrated for the duration T2 (see also FIG. 5) until the comparator threshold UCa-URb has been reached. During this time the switch 38a is open and the switch 37a is closed. After this, the integration is stopped and the output signal becomes inactive again. Thus the comparator threshold is again the starting value for the next integration, and the reference voltage URb does not form part of the output pulse duration T2:

$$T {2}_{MN} = T 1 \cdot ( \frac{UCa}{URa} - 1 )$$

During the test mode MT, by means of the integrator the voltage UCa-URa is again negatively integrated during the reference period T1. In this arrangement the switch 38a is again closed, and the switch 37a is open. However, in this arrangement the period T1 is selected in such a manner that the output of the operational amplifier 30a reliably reaches zero, even with minimal cell voltage, and remains at zero. After the end of the reference period T1 the optocoupler 6a on the output side is switched over, and during the period T2 the reference voltage URa is positively integrated until the comparator threshold UCa-URb has been reached again. During this period the switch 38a is open, and the switch 37a is closed. After this, the integration is stopped and the output signal is inactive again. The period T2 now no longer depends on T1 but instead on the value of the resistor 31, on the capacity of the capacitor 32 and on the reference voltage URb:

$$T {2}_{MT} = {R}_{31} {C}_{32} \cdot ( \frac{UCa}{URa} - \frac{URb}{URa} )$$

if URa≈URb, then

$$T {2}_{MT} \approx T {2}_{MN} \cdot \frac{{R}_{31} {C}_{32}}{T 1}$$

provided that UCa has not changed. Any major deviation of T2_{MT} from the above setpoint value would indicate that URa or URb is no longer correct. In this arrangement the values relating to C32 can, for example, be stored during initial operation.

Finally it should be noted that the variants shown provide only some of the many options relating to an accumulator 1 according to the invention, a cell monitoring unit 3a . . . 3n according to the invention, and a central monitoring unit 4 according to the invention, and must not be used to limit the scope of the invention. To the average person skilled in the art it should be easy to adapt the invention to their own requirements, based on the considerations presented in this document, without in this process leaving the scope of protection of the invention. Moreover, it should be noted that parts of the devices shown in the figures can also form the basis for independent inventions.

### LIST OF REFERENCE LABELS

1 Accumulator
2, 2a . . . 2n Cells
3, 3a . . . 3n Cell monitoring unit
4 Central monitoring unit
5, 5a Optocoupler on the input side
6, 6a, 6b Optocoupler on the output side
7 Transducer
8, 8a, 8b Reference source
9, 9a Current source
10 Microcontroller
11 . . . 14 Comparator
15 . . . 17 Voltage source
18, 19 Resistor
20 Switch
21 Diodes
22 Setting-value converter
23 Cell regulator
24 Transistor
25 Resistor
26a . . . 26n D-flip-flop
27a . . . 27n AND gate
28a . . . 28n Changeover switch
29 Comparator
30a, 30b Operational amplifier
31a Resistor
32a Capacitor
33a, 33b Resistor
34a Operational amplifier
35a Resistor
36a Comparator
37a, 37b Switch
38a Switch
39a OR gate
40a, 40b Resistor
B Data bus
IL2 . . . IL3 Current through lines L2 . . . L3
L1 . . . L7 Signal lines
MN Normal mode
MT Test mode
U11 . . . U14 Output voltages of the comparators 11 . . . 14
U18, U19 Voltage on resistors 18, 19
UCa, UCb Cell voltage
UIa Integrator voltage
URa, URb Reference voltage

What is claimed is:

1-14. (canceled)

15. A method of monitoring a plural-cell accumulator comprising:
determining a plurality of respective measurement values of a cell parameter respectively in each of a plurality of cells of the accumulator;
outputting a plurality of respective measurement signal currents based on each of said plurality of respective measurement values of the cell parameter; and,
synchronously transmitting as a stepped summation measurement current the plurality of measurement signal currents, by a pulse-width modulated signal, to a central monitoring unit.

16. A method of monitoring a plural-cell accumulator as claimed in claim 15, further comprising:
analyzing the stepped summation measurement current in the central monitoring unit to isolate a measurement signal current from the stepped summation measurement current.

17. A method of monitoring a plural-cell accumulator as claimed in claim 16, further comprising:
isolating the first step of the stepped summation measurement current as an extreme value of the cell parameter in the accumulator.

18. A method of monitoring a plural-cell accumulator as claimed in claim 16, further comprising:
isolating the last step of the stepped summation measurement current as an extreme value of the cell parameter in the accumulator.

19. A method of monitoring a plural-cell accumulator as claimed in claim 16, further comprising:
isolating the first step of the stepped summation measurement current as an extreme value of the cell parameter in the accumulator; and,
isolating the last step of the stepped summation measurement current as an extreme value of the cell parameter in the accumulator.

20. A method of monitoring a plural-cell accumulator as claimed in claim 16, further comprising:
setting the plurality of measurement signal currents to have an identical current level; and,
isolating a measurement signal current from the stepped summation measurement current when the central monitoring unit detects that the stepped summation measurement current crosses, between two steps, a selected voltage threshold value.

21. A method of monitoring a plural-cell accumulator as claimed in claim 20, further comprising:
selecting the voltage threshold value at half of the voltage generated by the identical current level of the plurality of measurement signals.

22. A method of monitoring a plural-cell accumulator as claimed in claim 20, further comprising:
selecting the voltage threshold value at one and one-half of a voltage generated by the identical current level of the plurality of measurement signals.

23. A method of monitoring a plural-cell accumulator as claimed in claim 15, further comprising:
setting the plurality of measurement signal currents to have a binary coded relation of current levels.

24. A method of monitoring a plural-cell accumulator as claimed in claim 15, further comprising:
excluding from the stepped summation measurement current the measurement value of cell parameter of a selectively excluded one of the plurality of cells of the accumulator; and,
individually transmitting, in parallel to the stepped summation measurement current, to the central monitoring unit the excluded measurement valued of the selectively excluded cell.

25. A method of monitoring a plural-cell accumulator as claimed in claim 15, further comprising:
in time-division multiplex succession selectively excluding from the stepped summation measurement current the measured values of cell parameter of selectively excluded cells.

26. A method of monitoring a plural-cell accumulator as claimed in claim 15, further comprising:
providing a respective reference value of the cell parameter for each respective one of the plurality of cells of the accumulator;
measuring the actual respective cell parameter in each respective cell; and,
determining the respective measurement value of the cell parameter in each respective cell as the deviation of the respective actual cell parameter from the respective reference value.

27. A method of monitoring a plural-cell accumulator as claimed in claim 26, further comprising:
comparing respective reference values of adjacent cells in a periodically recurring manner; and,
issuing an error message if the comparing of respective reference values yields a deviation exceeding a specifiable limit value.

28. A method of monitoring a plural-cell accumulator as claimed in claim 15, further comprising:
providing a respective cell temperature as the respective cell parameter;
activating a heater thermally coupled to the respective cell when the respective cell temperature is lower than a limit value.

29. A method of monitoring a plural-cell accumulator as claimed in claim 15, further comprising:
providing a respective cell voltage as the respective cell parameter;
shunting current from the cell when the respective cell voltage exceeds a limit value.

30. A multi-cell accumulator unit comprising:
a plurality of cells;
a plurality of cell monitoring units each respectively connected to a respective cell, each cell monitoring unit including a respective sensor configured to measure a respective parameter of the respective cell and output a respective resultant signal current; and,
a transmitter arrangement configured to synchronously transmit under pulse-width modulation control said plurality of resultant signal currents as a stepped summation measurement current, said transmitter arrangement connected to transmit said stepped summation measurement current to a central monitoring unit.

31. A multi-cell accumulator unit as claimed in claim 30, further comprising:
in said transmitter arrangement, a respective transmitter for each respective cell monitoring unit.

32. A multi-cell accumulator unit as claimed in claim 30, further comprising:
a circuit configured to detect a step in said stepped summation measurement current.

33. The multi-cell accumulator unit as claimed in claim 30, wherein:
said central monitoring unit is connected to provide a pulse-width modulation signal to said plurality of cell monitoring units.

34. A multi-cell accumulator unit as claimed in claim 30, further comprising:
a sensor configured to measure cell temperature; and
a cell heater configured to supply heat to a cell when said sensor measures a cell temperature lower than a limit value.

35. A multi-cell accumulator unit as claimed in claim 30, further comprising:
circuitry configured to selectively exclude from said stepped summation measurement current, in time-division multiplex succession, the measured value of cell parameter of selectively excluded cells.

36. A multi-cell accumulator unit as claimed in claim 35, further comprising:
said circuitry has connections configured to individually transmit to said central monitoring unit said selectively excluded measured value of cell parameter, said connections being in parallel to said transmission arrangement connection transmitting said stepped summation measurement current to said central monitoring unit.

37. A multi-cell accumulator unit as claimed in claim 30, further comprising:
a respective reference value generator in each of said plurality of cell monitoring units, said respective reference value generator connected to circuitry configured to output said respective resultant signal current based on a comparison of a respective generated reference value against said measurement of said respective parameter of the respective cell.

38. A multi-cell accumulator unit as claimed in claim 37, further comprising:
comparison circuitry configured to compare respective generated reference values of adjacent ones of said plurality of cells.
